(19) United States
(12) Patent Application Publication
(10) Pub. No.: US 2026/0114040 A1
(43) Pub. Date: Apr. 23, 2026

(54) INTEGRATED CIRCUIT DEVICES INCLUDING MODIFIED CSMOB REGIONS AND METHODS OF FORMING THE SAME

(71) Applicant: Samsung Electronics Co., Ltd., Suwon-si (KR)

(72) Inventors: Jongmin Shin, Niskayuna, NY (US); Beomjin Park, Clifton Park, NY (US); Kang-ill Seo, Springfield, VA (US)

(21) Appl. No.: 19/221,610

(22) Filed: May 29, 2025

Related U.S. Application Data
(60) Provisional application No. 63/710,624, filed on Oct. 23, 2024.

(51) Int. Cl. H10D 84/85; H01L 23/00; H01L 23/522; H01L 23/528; H10D 30/00; H10D 30/01; H10D 30/43; H10D 62/10; H10D 84/01

(52) U.S. Cl. CPC H10D 84/851; H10D 30/014; H10D 30/0191; H10D 30/43; H10D 30/502; H10D 62/121; H10D 84/0167; H10D 84/856; H10W 20/42; H10W 20/435; H10W 42/00; H10W 42/121

(57) ABSTRACT

A circuit device includes a substrate having an active region and an inactive region adjacent a periphery of the active region, lower channel structures respectively comprising one or more lower channel patterns stacked on the substrate in the active region and in the inactive region, isolation patterns on the lower channel structures opposite the substrate, and upper channel structures respectively comprising one or more upper channel patterns stacked on the isolation patterns opposite the lower channel structures. The one or more lower channel patterns in the inactive region are free of the one or more upper channel patterns thereon.

### CLAIM OF PRIORITY

This application claims priority from U.S. Provisional Patent Application No. 63/710,624 entitled “Integrated circuit devices and methods of forming the same,” filed Oct. 23, 2024, with the United States Patent and Trademark Office, the disclosure of which is incorporated by reference herein in its entirety.

### TECHNICAL FIELD

The present disclosure relates to integrated circuit devices.

### BACKGROUND

The size of transistors in integrated circuit devices has continued to decrease in order to maintain downscaling of logic elements. Technology to increase transistor density and concentrate more transistors within the same area has continued to develop. As such, three-dimensional (3D) device structures are under consideration, and 3D stacking processes have been proposed.

One type of 3D device structure is a stacked transistor. Integrated circuit devices may utilize stacked transistors to increase density and improve performance. In some instances, the stacked transistors may be complementary to each other (e.g., complementary metal-oxide-semiconductor (CMOS) transistors). For example, a Complementary-FET (CFET) layout may include multiple vertically stacked pairs of gate-all-around field effect transistors (GAAFETs), with P-type GAAFETs on one-level, N-type GAAFETs on another level (i.e., above or below), and shared gates, where each shared gate extends between and wraps around the channel patterns of the stacked pair of N-type and P-type GAAFETs. In such structures, the source/drain regions of the lower GAAFET are electrically isolated from the source/drain regions of the upper GAAFET by dielectric layers.

Dozens or hundreds of integrated circuits are typically manufactured on a single semiconductor wafer. The individual die are singulated by sawing the integrated circuits along a scribe line, also referred to herein as dicing. The individual die are then packaged, either separately or in a multi-chip module or other type of packaging, for example.

After completing wafer level transistor fabrication and proceeding with dicing or packaging, an integrated circuit chip should exhibit resistance to moisture and other environmental factors to ensure reliable operation. For example, during a dicing process, where semiconductor wafers are cut into individual integrated circuit chips, there is a risk that one or more of the chips may break or crack due to stress, for example, proximate the scribe line. The cracks can disrupt conductive lines, which may render circuits inoperable, and/or can allow moisture and other contaminants into the integrated circuit, which may cause corrosion.

A crack stopper and moisture barrier (CSMOB) region or structure may be helpful for preventing chip breakage and cracks during the dicing process. The CSMOB region may also help prevent (i.e., may block) moisture penetration into the chip during a packaging process. In some embodiments, the CSMOB region may include one or more protective layers formed as a dam around the periphery or outer area of the chip, to protect an inner region/area (e.g., the device region) of the chip.

### SUMMARY

According to some embodiments, a circuit device includes a substrate that has an active region and an inactive region adjacent to the periphery of the active region. Lower channel structures comprising one or more lower channel patterns stacked on the substrate are provided in the active and inactive regions. Isolation patterns are provided on the lower channel structures opposite the substrate. Upper channel structures comprising one or more upper channel patterns are stacked on the isolation patterns, opposite the lower channel structures. In the inactive region, the lower channel patterns are free of upper channel patterns thereon.

In some embodiments, the circuit device includes gate patterns that extend in a first direction on the lower channel patterns in the active and inactive regions. In the inactive region, the lower channel patterns extend in the first direction, while in the active region, the lower channel patterns extend in a second direction that intersects the first direction. In some embodiments, in the inactive region, the lower channel patterns are parallel to the gate patterns, while in the active region, they are orthogonal to the gate patterns.

In some embodiments, the circuit device comprises conductive patterns that extend in the first direction on the lower channel patterns in the inactive region. The conductive patterns are narrower than the lower channel patterns in a second direction that intersects the first direction.

In some embodiments, the conductive patterns contact at least one of the lower channel patterns in the lower channel structures of the inactive region free of metal gate patterns therebetween.

In some embodiments, the conductive patterns extend into surfaces of the lower channel structures in the inactive region, opposite the substrate, to contact at least one of the lower channel patterns. At least one lower channel pattern may be provided between the conductive patterns and the substrate.

In some embodiments, the conductive patterns extend into a surface of the substrate, opposite the lower channel structures in the inactive region, to contact at least one lower channel pattern.

In some embodiments, the conductive patterns may include multiple stacked metal patterns and/or conductive via structures located on respective metallization levels of the circuit device.

In some embodiments, the upper channel patterns of the upper channel structures have widths that are narrower than those of the lower channel patterns in the lower channel structures.

In some embodiments, the lower channel patterns in the inactive region maintain the same width, while in a specific region known as the crack stopper moisture barrier (CSMOB) region, the lower channel patterns are narrower than those in the active region.

In some embodiments, the inactive region may be a CSMOB region, which extends along the periphery of the active region.

In some embodiments, in the active region, the lower and upper channel patterns include lower and upper nanosheets that extend between lower and upper source/drain regions of first and second transistors, respectively.

In some embodiments, the lower source/drain regions have a first conductivity type, while the upper source/drain regions have a second conductivity type opposite to the first.

According to some embodiments, a circuit device includes a substrate having an active region and a CSMOB region along a periphery of the active region. Lower nanosheet stacks comprising one or more lower nanosheet channel patterns are stacked on the substrate in the active and CSMOB regions. Upper nanosheet stacks comprising one or more upper nanosheet channel patterns are stacked on the lower nanosheet stacks, with respective isolation patterns therebetween. Conductive patterns extend in a first direction in the CSMOB region and are on the lower nanosheet patterns free of the upper nanosheet patterns therebetween.

In some embodiments, the lower nanosheet channel patterns in the CSMOB region are free of upper nanosheet channel patterns.

In some embodiments, the conductive patterns in the CSMOB region include gate patterns that extend in the first direction on the lower nanosheet channel patterns. The lower nanosheet channel patterns in the CSMOB region extend in the first direction, while the lower nanosheet channel patterns in the active region extend in a second direction that intersects the first direction.

In some embodiments, the conductive patterns in the CSMOB region are narrower than the lower nanosheet channel patterns in the second direction that intersects the first direction.

In some embodiments, the CSMOB region is free of metal gate patterns, and the conductive patterns extend into the surfaces of the lower nanosheet stacks, opposite the substrate, to contact at least one lower nanosheet channel pattern. At least one lower nanosheet channel pattern is located between the conductive patterns and the upper surface of the substrate.

In some embodiments, in the CSMOB region, the conductive patterns may extend into a surface of the substrate, opposite the lower nanosheet stack, to contact at least one lower nanosheet channel pattern.

In some embodiments, the upper nanosheet channel patterns are narrower than the lower nanosheet channel patterns.

According to some embodiments, a method of fabricating a circuit device includes forming channel layers and sacrificial layers that are alternately stacked on a substrate in an active region and a CSMOB region extending along the periphery of the active region. The method further includes performing at least one etching process on the channel layers and sacrificial layers to form lower channel structures comprising one or more lower channel patterns, sacrificial isolation patterns on the lower channel structures, and upper channel comprising one or more upper channel patterns stacked on sacrificial isolation patterns opposite the lower channel structures. The etching process selectively removes the upper channel patterns in the CSMOB region of the substrate.

In some embodiments, the before the etching process, a mask pattern is formed on a portion of the channel layers and sacrificial layers in the active region. As a result of the etching process, the upper channel patterns in the active region are narrower than the lower channel patterns, while the lower channel patterns in the CSMOB region are free of upper channel patterns.

In some embodiments, the method further includes forming gate patterns that extend in a first direction on the lower channel patterns in the active and CSMOB regions. In the CSMOB region, the lower channel patterns extend in the first direction, while in the active region, the lower channel patterns extend in a second direction that intersects the first direction.

In some embodiments, the method further includes forming conductive patterns that extend in the first direction on the lower channel patterns in the CSMOB region. The conductive patterns are narrower than the lower channel patterns in a second direction that intersects the first direction.

In some embodiments, in the CSMOB region, the conductive patterns extend into surfaces of the lower channel structures, opposite the substrate, to contact at least one lower channel pattern.

In some embodiments, forming the conductive patterns further includes patterning a surface of the substrate, opposite the lower channel structures, to create openings. Conductive patterns are formed in the openings in the surface of the substrate to contact at least one lower channel pattern of the lower channel structures.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a plan or layout view illustrating a semiconductor wafer including semiconductor integrated circuit devices according to some embodiments of the present disclosure.

FIG. 1B is an enlarged view of region 1B of FIG. 1A illustrating a semiconductor integrated circuit device according to some embodiments of the present disclosure.

FIG. 1C is an enlarged view of region 1C of FIG. 1B.

FIG. 2A illustrates cross sectional views taken along line A-A of FIG. 1B, illustrating channel patterns in an active region and an inactive region of a semiconductor integrated circuit device according to some embodiments.

FIG. 2B illustrates cross sectional views taken along line B-B of FIG. 1B, illustrating channel patterns in an active region and an inactive region of a semiconductor integrated circuit device according to some embodiments.

FIG. 2C illustrates cross sectional views taken along line C-C of FIG. 1B, illustrating channel patterns in an active region and an inactive region of a semiconductor integrated circuit device according to some embodiments.

FIGS. 3A, 3B, 3C, and 3D are cross-sectional views taken along line A-A of FIG. 1B, illustrating channel patterns and metal layers thereon in an inactive region of a semiconductor integrated circuit device according to some embodiments.

FIGS. 4A, 4B, 4C, and 4D are cross-sectional views taken along line A-A of FIG. 1B, illustrating channel patterns and metal layers thereon in an inactive region of a semiconductor integrated circuit device according to further embodiments.

FIGS. 5A, 5B, 5C, and 5D are cross-sectional views taken along line A-A of FIG. 1B, illustrating channel patterns and metal layers thereon in an inactive region of a semiconductor integrated circuit device according to still further embodiments.

FIGS. 6A, 6B, 6C, 6D, 6E and 6F are cross-sectional views taken along line C-C of FIG. 1B, illustrating example fabrication operations in methods of fabricating channel patterns in an active region of a semiconductor integrated circuit device according to some embodiments.

FIGS. 7A, 7B, 7C, 7D, 7E and 7F are cross-sectional views taken along line C-C of FIG. 1B, illustrating example fabrication operations in methods of fabricating channel patterns in an inactive region of a semiconductor integrated circuit device according to some embodiments.

FIG. 8 is a flowchart illustrating example fabrication operations in methods of fabricating channel patterns in an active region and an inactive region of a semiconductor integrated circuit device according to some embodiments.

### DETAILED DESCRIPTION OF EMBODIMENTS

In embodiments described herein, a stacked transistor structure may include a first transistor and a second transistor. The first transistor may be a first type of transistor (e.g., an n-type field-effect transistor (nFET), such as an n-type metal-oxide-semiconductor (NMOS) transistor), and the second transistor may be a second type of transistor (e.g., a p-type field-effect transistor (pFET), such as a p-type metal-oxide-semiconductor (PMOS) transistor). The first and second transistors may be stacked in any order (e.g., first on top of second, or second on top of first), resulting in a stacked structure (e.g., a stacked FET structure such as a 3D stacked FET (3DSFET)) including a top device (also referred to herein as an upper device or upper transistor, relative to an underlying substrate) and a bottom device (also referred to herein as a lower device or lower transistor, relative to the underlying substrate). In some stacked transistors, channel patterns of the upper and lower transistors (also referred to as upper and lower channel patterns, respectively) may be implemented as nanosheets (which may have a thickness of about 1 nanometer to about 100 nanometers) or nanowires (which may have a diameter of about 1 nanometer to about 100 nanometers), which may be vertically stacked and at least partially surrounded by gate patterns to improve channel control.

A 3DSFET may also include a dielectric layer (which may also be referred to as a middle dielectric isolation (MDI) region) that separates the upper and lower devices of the 3DSFET. To form the MDI region, a sacrificial isolation pattern (such as a silicon germanium (SiGe) layer) may be removed and replaced with a dielectric material.

Some embodiments of the present disclosure may arise from realization that, while the device active region of an integrated circuit chip may include gates and nanosheets (or other channel pattern(s)) that extend orthogonal to each other, the gate and channel pattern(s) in the crack stopper and moisture barrier (CSMOB) region may be aligned or may extend (e.g., longitudinally) in the same direction (e.g., may extend parallel to each other). That is, in the CSMOB region, the extension direction of the gates may not be orthogonal (e.g., may not extend perpendicular) to the channel pattern(s) (or the gates may not be present at all). For example, generally, the gates are oriented vertically, while nanosheets may extend horizontally. However, in the CSMOB region, the gates and nanosheets may extend diagonally, e.g., horizontally and vertically surrounding the logic region. Also, nanosheets and gates may be aligned in the same direction during formation.

Due to the configuration of the channel patterns and the gates in the CSMOB region, removing the sacrificial (e.g., SiGe layer) between upper and lower channel patterns (in order to form the MDI region) may cause the upper nanosheets and one or more layers of the gates (e.g., the gate work function and/or gate metal layer(s)) to become detached.

Example embodiments of the present disclosure are directed to improving or optimizing the CSMOB region in integrated circuit devices (e.g., 3DSFETs). In particular, the upper and lower transistor structures may be formed with a different configuration in the CSMOB region, in comparison to the device region. For example, by removing an upper epitaxial structure (e.g., upper channel patterns or nanosheet region(s)) in the CSMOB region, while retaining the lower epitaxial structure (e.g., the lower channel patterns or nanosheet region(s)), the upper epitaxial structure and the gate may not become released (i.e., may be prevented from becoming detached) in the CSMOB region during removal of the sacrificial layer(s) to form the MDI region. In some embodiments, one or more (or all) patterns (e.g., channel patterns/nanosheets, gates, and metal lines) in the CSMOB region may be formed in the same direction (e.g., may be parallel to each other), and in a BSPDN structure, one or more metal lines may be formed in the CSMOB region. Embodiments of the present disclosure may be applied to I-shaped and L-shaped 3DSFETs, or any configuration where channel patterns of first and second transistor structures are stacked on one another with an isolation layer (e.g., MDI) therebetween.

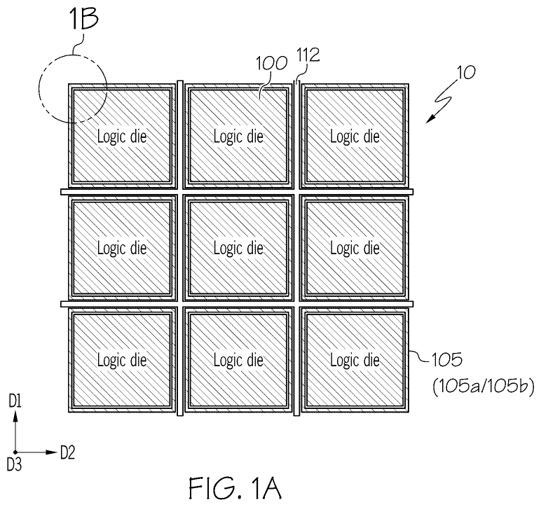

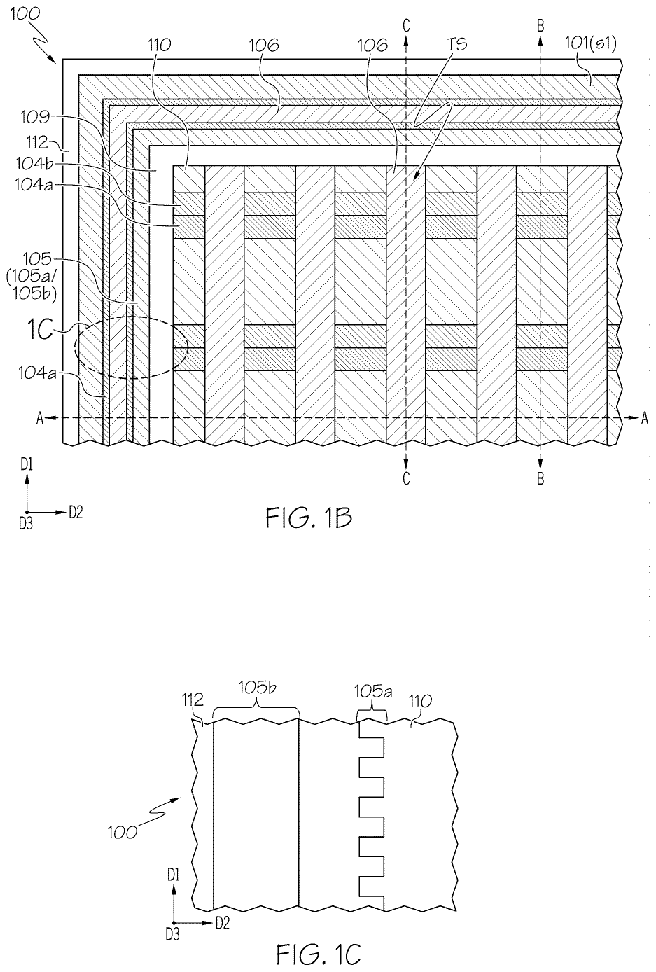

FIG. 1A is a plan or layout view illustrating a semiconductor wafer 10 according to some embodiments of the present disclosure. FIG. 1B is an enlarged view of region 1B of FIG. 1A illustrating a semiconductor integrated circuit device 100 according to some embodiments of the present disclosure. FIG. 1C is an enlarged view of region 1C of FIG. 1B.

Referring to FIGS. 1A to 1C, the integrated circuit device 100 may be a die that is formed on a semiconductor wafer 10. The wafer includes multiple dies 100, with each individual die 100 having a distinct substrate 101, an integrated circuit active area or active region 110, and an inactive area or inactive region 105 adjacent the periphery of the active region 110. The dies 100 are separated from the wafer (also referred to as a singulation process) along scribe lines or saw street areas 112, by sawing or cutting using a mechanical process (also referred to as dicing) or by a non-contact process (such as with a laser). The inactive region 105 may include a die seal ring structure (including a crack stop structure 105b and a moisture barrier region 105a, collectively referred to as a crack stopper moisture barrier (CSMOB) region 105a/105b) which extends along the periphery of the active region 110 of each die 100 to prevent or reduce the likelihood of cracking in the die 110 during the separation process. The scribe lines 112 separates adjacent dies 100 on the wafer.

The CSMOB region 105a/105b surrounds the logic die in a linear shape in plan view, and is located inside the scribe line 112. The shape of CSMOB 105a/105b is illustrated in FIG. 1A as a linear shape, but it can also be designed in various shapes such as maze or zigzag, as shown in FIG. 1C.

As shown in FIG. 1B, each integrated circuit device 100 may include a plurality of transistor structures TS (also referred to as transistors) in the active region 110 on a first side (or frontside) S1 of the substrate 101. The substrate 101 may extend in a first direction D1 (also referred to as a first horizontal direction or Y direction) and a second direction D2 (also referred to as a second horizontal direction or X direction) that intersects the first direction D1. The first direction D1 and the second direction D2 may be parallel to a surface (e.g., the frontside S1) of the substrate 101. In some embodiments, the first direction D1 may be perpendicular to the second direction D2.

In some embodiments, the substrate 101 may include or may be semiconductor material(s), for example, Si, Ge, SiGe, GaP, GaAs, SiC, SiGeC and/or InP. For example, the substrate 101 may be insulating layer(s), a bulk substrate (e.g., a bulk silicon wafer) and/or a semiconductor-on-insulator (SOI) substrate. In some embodiments, the substrate 101 may include or may be formed of insulating material(s), for example, silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric. A thickness of the substrate 101 in a third direction D3 (also referred to as a vertical direction or Z direction) may be, for example, in a range of (about) 50 nm to 100 nm. In some embodiments, the third direction D3 may be perpendicular to the first direction D1 and/or the second direction D2. The third direction D3 may be perpendicular to the surface (e.g., the frontside S1) of the substrate 101.

Each of the transistor structures TS may include a gate structure including a gate 106 and a channel structure 104 including channel patterns 104a and 104b (e.g., lower channel patterns 104a and upper channel patterns 104b, described in greater detail below) that extend between source/drain regions (not shown). The gates (also referred to as gate lines, such as metal gate lines) 106 may overlap the channel patterns 104a, 104b in the third direction D3. The gates 106 may extend in the first direction D1, and the channel patterns 104a, 104b may extend in the second direction D2 between the source/drain regions. In some embodiments, each of the transistor structures TS may include multiple channel patterns 104a, 104b stacked in the third direction D3, and the channel patterns 104a, 104b may be spaced apart from each other in the third direction D3. For example, the transistor structures TS may be nanosheet transistors that include a stack of nanosheet layers provided by the channel patterns 104a, 104b.

Each of the transistor structures TS may also include a pair of the source/drain regions that are spaced apart from each other in the second direction D2. The source/drain regions may include a semiconductor layer (e.g., a silicon (Si) layer and/or a silicon germanium (SiGe) layer) and may additionally include dopants in the semiconductor layer. The gates 106 may be provided between the pair of source/drain regions. The source/drain regions may contact opposing side surfaces of the channel patterns 104a, 104b that are spaced apart from each other in the second direction D2.

The channel patterns 104a, 104b may include semiconductor material(s) (e.g., Si, Ge, SiGe, GaP, GaAs, SiC, SiGeC and/or InP). In some embodiments, the channel patterns 104a, 104b may include nanosheets that may have a thickness, for example, in a range from (about) 1 nanometer (nm) to 100 nm in the third direction D3, or may be nanowires having a circular cross-section with a diameter, for example, in a range of from (about) 1 nm to 100 nm. When the channel patterns 104a, 104b include a nanosheet or nanowire, the gate patterns 102 may extend around (e.g. to at least partially surround) the channel patterns 104a, 104b on multiple sides.

The integrated circuit device 100 may include multiple gates 106 that extend longitudinally in the first direction D1 and are spaced apart from each other in the second direction D2. Each of gates 106 may include a single layer or multiple layers. In some embodiments, each of the gates 106 may include a metal layer or material that includes, for example, tungsten (W), aluminum (Al), copper (Cu), molybdenum (Mo), cobalt (Co) and/or ruthenium (Ru), and may additionally include work function layer(s) (e.g., a TiN layer, a TaN layer, a TiAl layer, a TiC layer, a TiAlC layer, a TiAlN layer and/or a WN layer). In some embodiments, each of the gates 106 may include the same material(s).

In the example of FIG. 1B, the gates 106 extend on the channel structures 104 in the active region 110. In the active region 110, the channel patterns 104a, 104b extend in the second direction D2, intersecting (e.g., orthogonal to) the extension of the gates 106 in the first direction D1. However, in the inactive region 105, the (independently formed) channel patterns 104a also extend parallel to the gates 106 (e.g., in the first direction D1, or in the second direction D2). That is, in the CSMOB region 105a/105b, the channel patterns(s) 104a (i.e., the lower channel patterns) and the gates 106 (and/or other conductive patterns 308, as described below) may be aligned in the same direction. As described in greater detail below, the channel patterns 104b (i.e., the upper channel patterns) may not be provided in the CSMOB region 105a/105b. A region 109 between the active region 110 and the CSMOB region 105a/105b may be free of the channel patterns 104a (i.e., the lower channel patterns) and the channel patterns 104b (i.e., the upper channel patterns), and/or other semiconductor patterns.

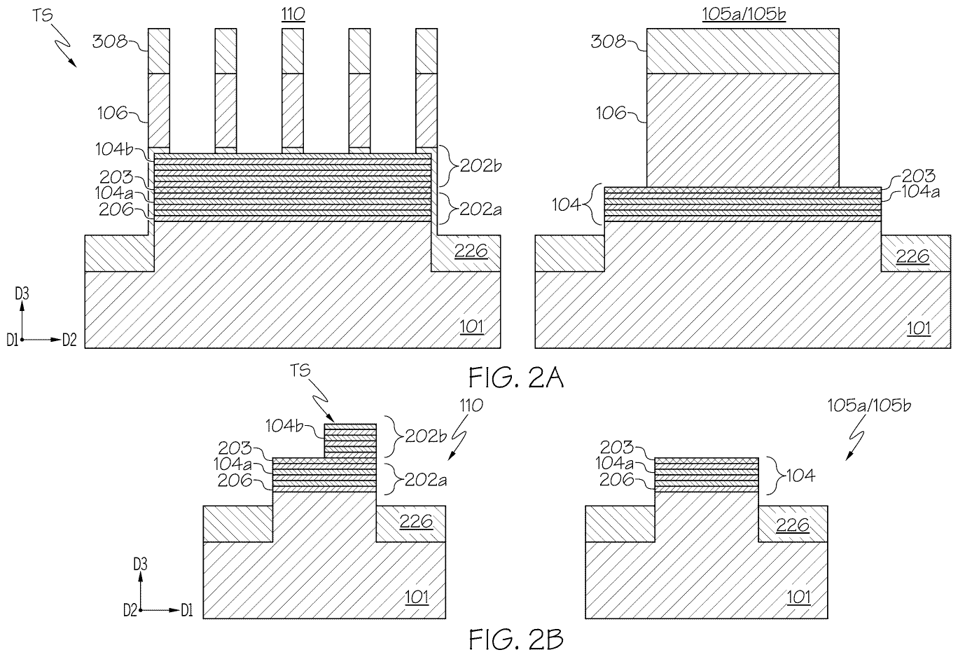

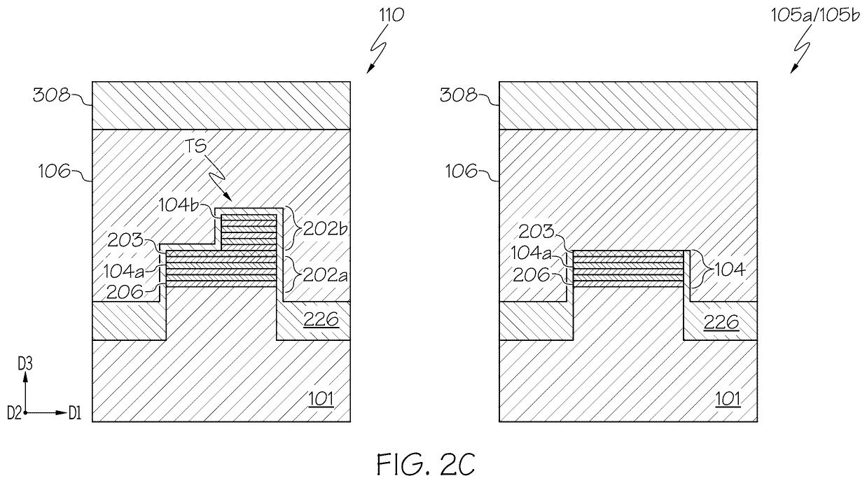

FIGS. 2A, 2B, and 2C are cross sectional views taken along lines A-A, B-B, and C-C of FIG. 1B, respectively, illustrating channel patterns in an active region 110 and an inactive region 105 of a semiconductor integrated circuit device according to some embodiments. The inactive region 105 includes a CSMOB region 105a/105b, which extends along the periphery of the active region 110. Isolation regions 226 (such as shallow trench isolation (STI) regions) are formed in the substrate 101 and extend along or around the active region 110 and at least a portion of the inactive region 105. The isolation regions 226 may include one or more dielectric materials such as SiO₂, and/or dielectric materials having a lower dielectric constant than SiO₂ (also referred to as low-k dielectrics).

As shown in FIGS. 2A, 2B, and 2C, the integrated circuit device 100 includes stacked transistor structures TS including first and second transistors 202a, 202b vertically stacked (in the direction D3) on the active region 110. The first transistor 202a includes lower channel patterns 104a between conductive gate patterns 206. The second transistor 202b includes upper channel patterns 104b between conductive gate patterns 206. The gate patterns 206 may similarly include lower gate patterns and upper gate patterns of the first transistor 202a and second transistor 202b, respectively.

In some embodiments, the transistor structure TS may be a three-dimensional (3D) field effect transistor (FET) such as a multi-bridge channel FET (MBCFET). In some embodiments, the transistor structure TS may have a structure different from that illustrated. For example, each of the lower and upper transistors 202a and 202b of the transistor structure TS may include a single channel pattern or a fin-shaped channel pattern (FinFET).

In the example of FIGS. 2A to 2C, multiple upper channel patterns 104b are stacked on multiple lower channel patterns 104a, with gate patterns 206 alternatingly stacked between the channel patterns 104a, 104b, but embodiments of the present disclosure may include fewer or more channel patterns than shown. In some embodiments, the lower channel patterns 104a may include lower nanosheets or lower nanosheet stacks of the first transistor 202a, and the upper channel patterns 104b may include upper nanosheets or upper nanosheet stacks of the second transistor 202b.

The channel patterns 104a, 104b may be formed of semiconductor materials, such as silicon (Si). In the active region 110, the lower and upper channel patterns 104a and 104b extend between lower and upper source/drain regions (not shown) of the first and second transistors 202a and 202b, respectively.

A gate insulating layer (also referred to as a gate insulator) may extend between the gate patterns 206 and the channel patterns 104a, 104b. More particularly, the gate insulator may contact and physically separate the gate patterns 206 and the channel patterns 104a, 104b (including nanosheets thereof). The gate insulator may include a single layer or multiple layers (e.g., a silicon oxide layer and/or a high-k dielectric material layer). For example, the high-k dielectric material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅.

Isolation patterns 203 (also referred to as a middle dielectric isolation (MDI) are provided on the stack of lower channel patterns 104a, opposite the substrate 101. In the active region 110, the isolation patterns 203 are provided between the stack of the lower channel patterns 104a of the first transistor 202a and the stack of the upper channel patterns 104b of the second transistor 202b. In the inactive region 105, the isolation patterns 203 are provided on the stack of lower channel patterns 104a. However, the lower channel patterns 104a are free of upper channel patterns 104b thereon in the inactive region 105. For example, in the CSMOB region 105a/105b, the isolation patterns 203 may be provided on upper surfaces of the lower channel patterns 104a (which may be lower nanosheet patterns) and the gate patterns 206, but the upper channel patterns 104b may not be provided on the isolation pattern 203.

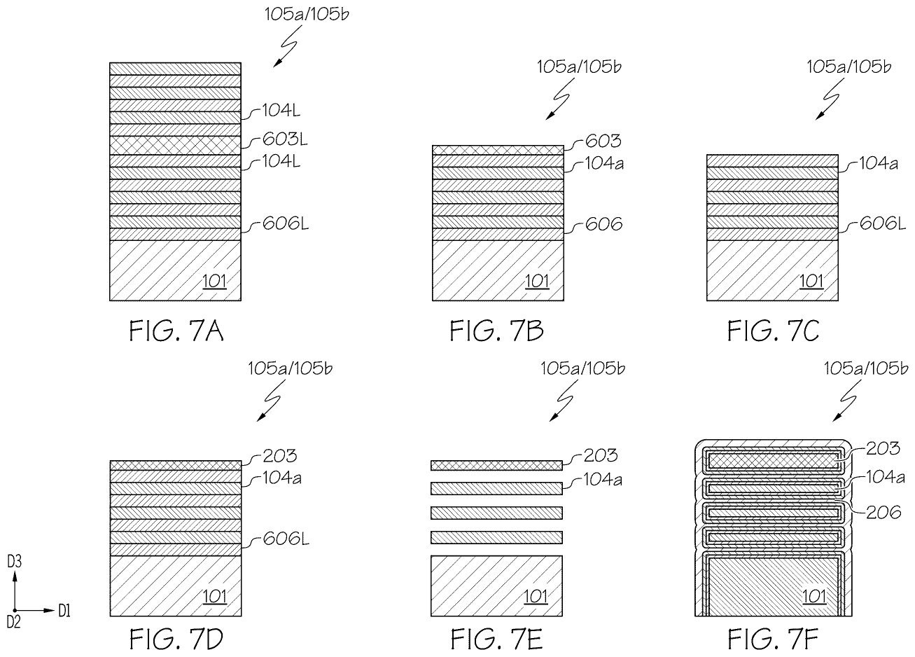

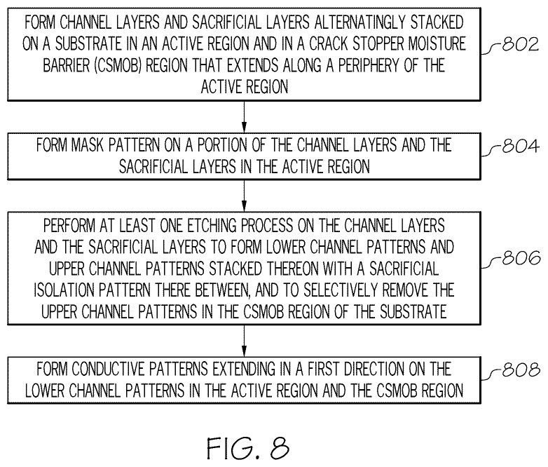

In some embodiments, the isolation patterns 203 may be omitted in the CSMOB region 105a/105b. That is, the isolation patterns or MDI 203 may or may not be present in the CSMOB region 105a/105b. For example, as described in greater detail below with reference to FIGS. 7A to 7F, during the etch process for removing the upper channel patterns 104b, the isolation patterns 203 may or may not be removed in the CSMOB region 105a/105b. Similarly, in some embodiments, the gate patterns 206 may be omitted in the CSMOB region 105a/105b. That is, a gate replacement process may or may not be performed in the CSMOB region 105a/105b, such that the channel structures 104 in the CSMOB region 105a/105b may include the gate patterns 206 in some embodiments, or may include dummy/sacrificial patterns (e.g., polysilicon patterns) 606L (see FIG. 7D) in other embodiments where the gate replacement process is not performed in the CSMOB region 105a/105b.

As shown in the cross-sections of FIGS. 2B and 2C, in the active region 110, the first and second transistors 202a and 202b may be implemented as “L-shaped” stacked transistor structures TS, where the upper channel patterns 104b have widths in the first direction D1 that are narrower than those of the lower channel patterns 104a. However, embodiments of the present disclosure are not limited to this configuration, and in other embodiments, the first and second transistors 202a and 202b may be implemented as “I-shaped” stacked transistor structures TS, where the upper channel patterns 104b and the lower channel patterns 104a have the same widths in the first direction D1. In the inactive region 105, the lower channel patterns 104a have the same width in the first direction D1. That is, because the inactive region 105 (including the CSMOB region 105a/105b) is free of the upper channel patterns 104b, all of the channel structures 104 in the inactive region 105 have substantially the same width dimensions.

As shown in the cross section of FIG. 2C, metal gate lines 106 and conductive patterns 308 extend on the lower and upper channel patterns 104a and 104b in the active region, but extend only on the lower channel patterns 104a in the inactive or CSMOB region 105a/105b. That is, in the CSMOB region 105a/105b, the metal gate lines 106 and/or conductive patterns 308 extend on the lower channel patterns 104a free of the upper channel patterns 104b therebetween. As noted, the metal gate lines 106 and/or the conductive patterns 308 may extend orthogonal to the channel patterns 104a, 104b in the active region 110, but may extend parallel to the channel patterns 104a in the CSMOB region 105a/105b.

In some embodiments, lower source/drain regions of the first transistor 202a may have a first conductivity type (e.g., n-type), while upper source/drain regions of the second transistor 202b may have a second, opposite conductivity type (e.g., p-type), or vice versa. That is, the first (lower) transistors 202a and second (upper) transistors 202b may have complementary conductivity types, e.g., to provide a CMOS device. Stacked transistor structures TS according to embodiments of the present disclosure are not limited to particular orientations of transistors having the different conductivity types. Moreover, the first and second transistors 202a and 202b may have the same conductivity type (e.g., both the first and second transistors 202a and 202b may be n-type, or both the first and second transistors 202a and 202b may be p-type) in some embodiments. Also, while illustrated with reference to first and second transistors 202a and 202b, it will be understood that stacked transistor structures TS according to embodiments of the present disclosure are not limited to two-transistor arrangement, and may include additional transistors (e.g., third transistors, fourth transistors, etc.) that are vertically stacked on the substrate 101 in the active region 110.

Although not shown in FIGS. 2A to 2C, the integrated circuit device 100 may also include a middle-of-line (MOL) structure and a back-end-of-line (BEOL) structure. Each of the MOL and BEOL structures may include interlayer insulating layer(s) in which conductive wire(s) (e.g., metal wire(s)) and conductive via plug(s) (e.g., metal via plug(s)) are provided. Various elements of the first transistor 202a and the second transistor 202b may be (electrically) connected to one of the conductive wires of the MOL and BEOL structures.

Further, in some embodiments, a backside power distribution network structure (BSPDNS) may be provided below or within the substrate 101. In some embodiments, some elements of the BSPDNS may be provided in the substrate 101. The BSPDNS may include backside insulating layer(s) in which conductive backside wire(s) (e.g., metal power rail(s)) and conductive backside contact(s) (e.g., backside metal contact(s)) are provided. Various elements of the first transistor 202a and the second transistor 202b may be (electrically) connected to one of the conductive backside wires.

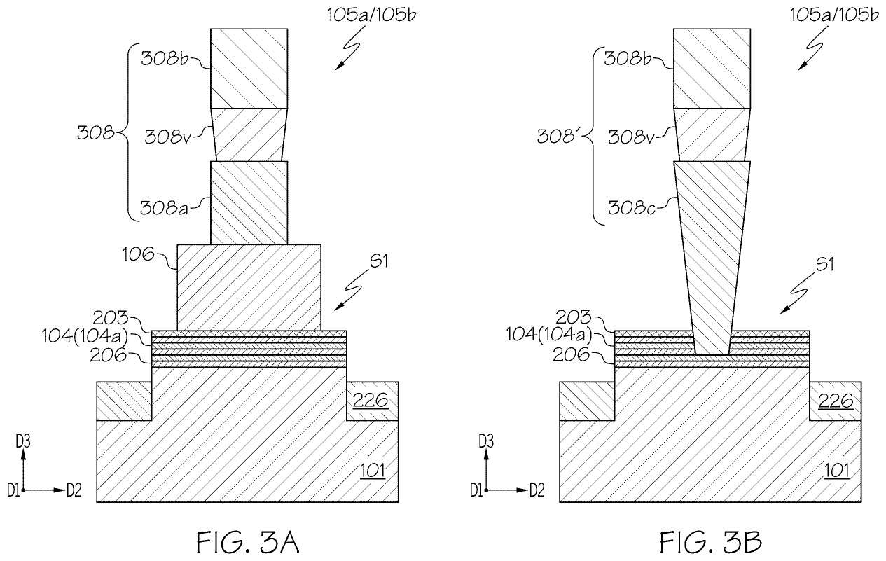

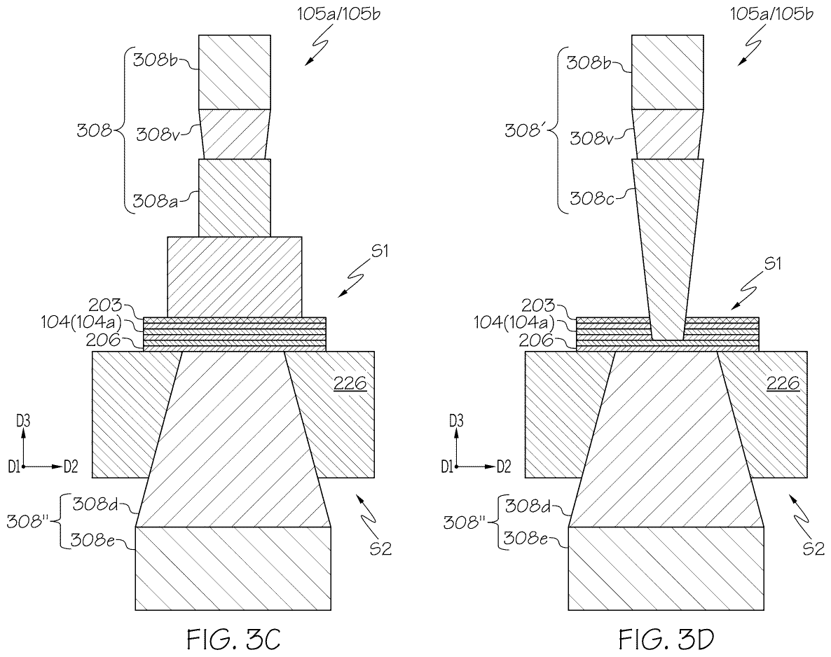

FIGS. 3A, 3B, 3C, and 3D are cross-sectional views taken along line A-A of FIG. 1B, illustrating channel patterns 104a with various configurations of metal gates 106 and/or conductive patterns 308 thereon in the CSMOB region 105a/105b of a semiconductor integrated circuit device 100 according to some embodiments.

As shown in FIGS. 3A to 3D, conductive patterns 308, 308′, 308″ (collectively, 308) extend in the first direction D1 on the lower channel patterns 104a in the inactive region 105. The conductive patterns 308 may be formed using various fabrication processes, including middle-end-of-line (MOL) and back-end-of line (BEOL) processes. The conductive patterns 308 may be narrower than the lower channel patterns 104a in the second direction D2. The conductive patterns 308 may include multiple stacked conductive patterns 308a, 308b, 308c, 308d, and/or 308e located on respective metallization levels (e.g., M1, M0, etc.) of the integrated circuit device 100, and/or conductive via structures 308v providing interconnections therebetween.

FIGS. 3A and 3B illustrate configurations including conductive patterns 308, 308′ on one side (illustrated as the front side S1) of the lower channel structures or stacks 104 in the CSMOB region 105a/105b. The conductive patterns 308, 308′ may be referred to as frontside conductive patterns. FIG. 3A illustrates routing of the metal gates 106 on the front side S1 of the device 100 in the CSMOB region 105a/105b between the lower channel structures 104 and the overlying conductive patterns 308. The metal gate lines 106 are separated from the lower channel patterns 104a by the isolation patterns 203. In the example of FIG. 3A, only one metal gate 106 is provided on each lower channel structure 104, and the conductive patterns 308 include gate contacts 308a, conductive vias 308v, and metal lines 308b (e.g., on the M1 metallization level).

FIG. 3B illustrates routing of the conductive patterns 308′ on the lower channel structures 104 on the front side S1 of the device 100 in the CSMOB region 105a/105b, free of intervening metal gate lines 106 therebetween. That is, the metal gates 106 may not be routed in the in the CSMOB region 105a/105b, such that the conductive patterns 308′ may be provided directly on the lower channel structures 104. In particular, the conductive patterns 308 may be provided in direct contact with at least one of the lower channel patterns 104a or gate patterns 206 of the lower channel structures 104 in the CSMOB region 105a/105b. The conductive patterns 308 may extend through the isolation patterns 203 on the surface of the lower channel structures 104, to directly contact at least one of the lower channel patterns 104a or gate patterns 206. In some embodiments, at least one lower channel pattern 104a or gate pattern 206 may be positioned between the conductive patterns 308 and the underlying substrate 101. In the example of FIG. 3B, only one frontside conductive pattern 308′ is provided on each lower channel structure 104, and the conductive patterns 308′ include top epitaxial contacts 308c (e.g., upper source/drain contacts), conductive vias 308v, and metal lines 308b.

FIGS. 3C and 3D illustrate configurations including conductive patterns 308, 308′, 308″ on both sides (illustrated as the front side S1 and the back side S2 of the device 100) of the lower channel structures or stacks 104 in the CSMOB region 105a/105b. FIG. 3C illustrates routing of the metal gates 106 on the front side S1 of the device 100 in the CSMOB region 105a/105b between the lower channel structures 104 and the overlying conductive patterns 308 (including gate contacts 308a, conductive vias 308v, and metal lines 308b) with the metal gate lines 106 separated from the lower channel structures 104 by the isolation patterns 203, similar to the configuration of the frontside conductive patterns 308 in FIG. 3A. FIG. 3D illustrates routing of conductive patterns 308′ on the lower channel structures 104 on the front side S1 of the device 100 in the CSMOB region 105a/105b and extending through the isolation patterns 203 to directly contact at least one of the lower channel patterns 104a or gate patterns 206, similar to the configuration of the frontside conductive patterns 308′ in FIG. 3B.

In addition, as shown in FIGS. 3C and 3D, conductive patterns 308″ extend into the back side S2 of device 100, which is opposite the lower channel structures 104. The conductive patterns 308″ may be referred to as backside conductive patterns 308″, which extend through surface of the underlying substrate (in this example, the isolation region 226) opposite the lower channel structures 104 to contact at least one lower channel pattern 104a or gate pattern 206. In the examples of FIGS. 3C and 3D, only one metal gate 106 and frontside conductive pattern 308 or 308″ and one backside conductive pattern 308″ are provided on a respective lower channel structure 104, and the backside conductive patterns 308″ include a backside epitaxial contact 308d (e.g., a lower source/drain contact) and a backside power rail 308e.

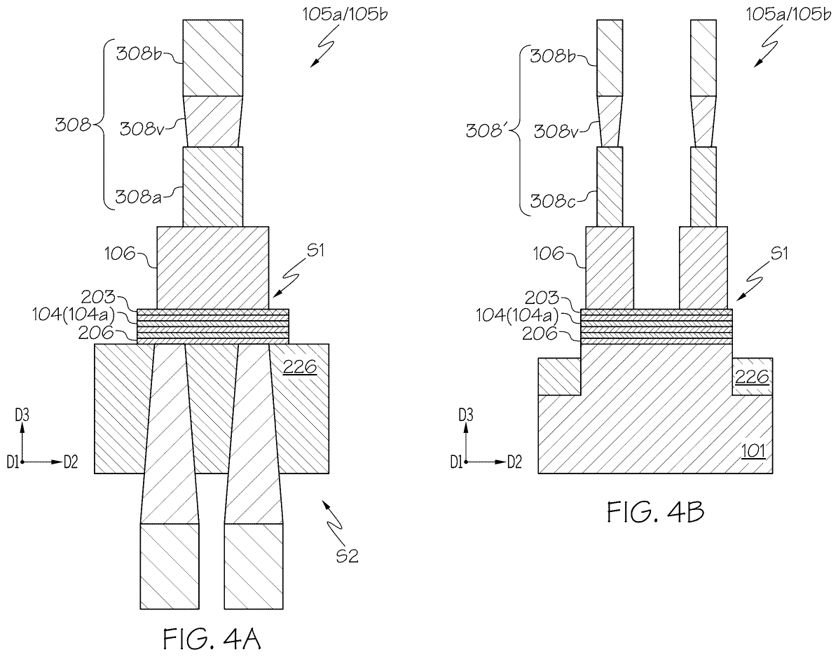

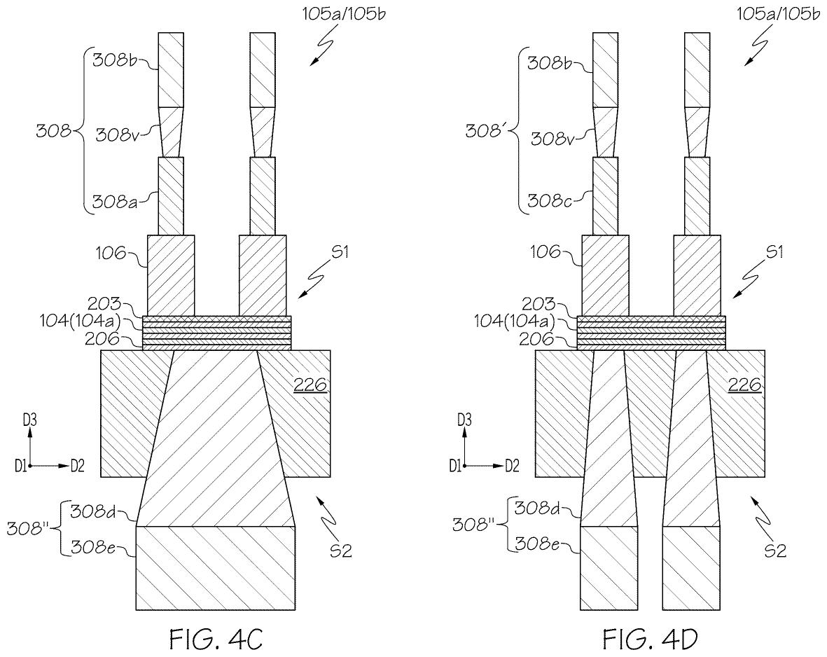

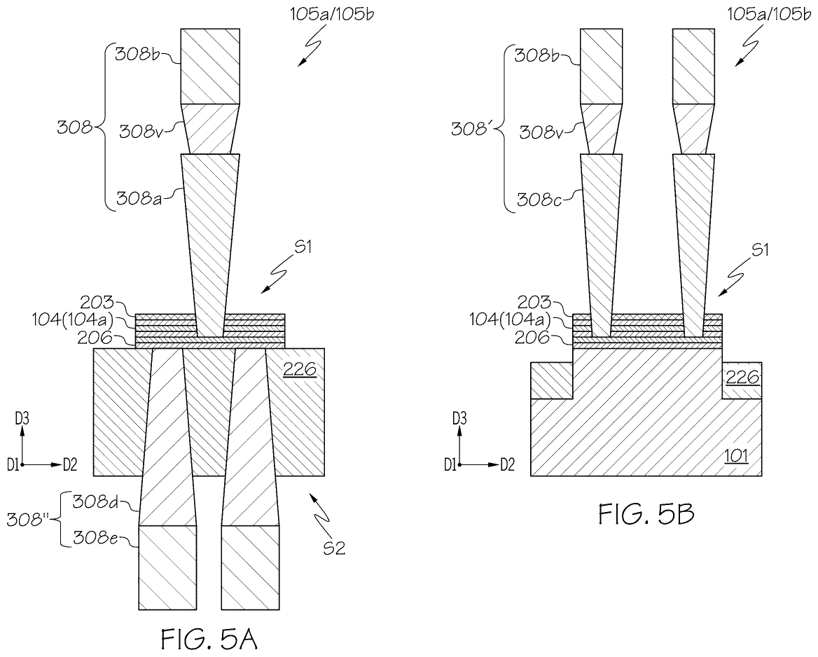

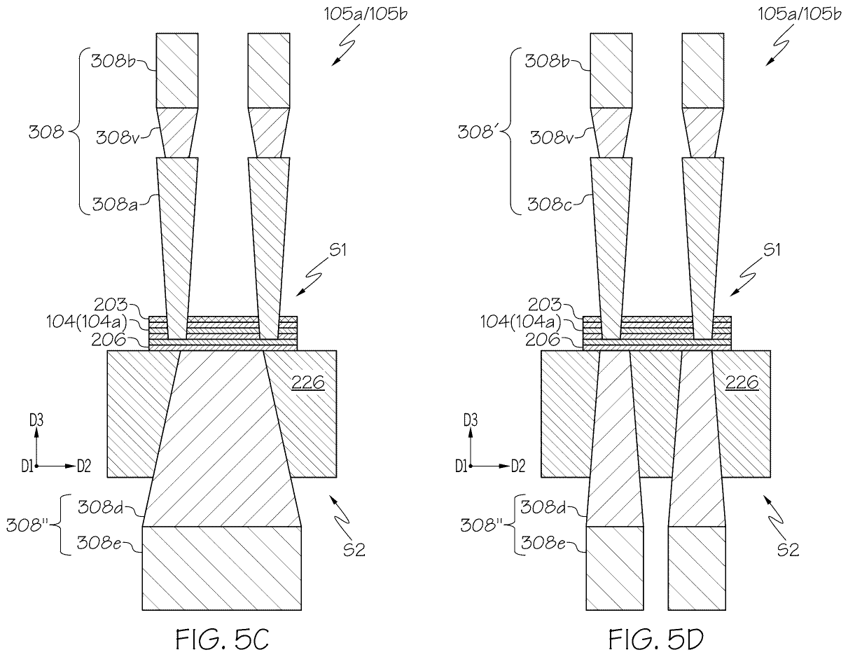

FIGS. 4A, 4B, 4C, and 4D are cross-sectional views taken along line A-A of FIG. 1B, illustrating channel patterns 104a with various configurations of metal gates 106 and conductive patterns 308 thereon in the CSMOB region 105a/105b of a semiconductor integrated circuit device 100 according to some embodiments. FIGS. 5A, 5B, 5C, and 5D are cross-sectional views taken along line A-A of FIG. 1B, illustrating channel patterns 104a with various configurations conductive patterns 308 thereon, free of metal gates 106 therebetween, in the CSMOB region 105a/105b of a semiconductor integrated circuit device 100 according to some embodiments. The metal gates 106 and conductive patterns 308, 308′, 308″ provided on each lower channel structure 104 may vary in these examples, but may include sublayers and/or configurations similar to those described above with reference to FIGS. 3A to 3D, unless otherwise described.

FIGS. 4A and 5A illustrate routing of the conductive patterns 308, 308′, 308″ on both sides (illustrated as the front side S1 and the back side S2 of the device 100) of the lower channel structures or stacks 104 in the CSMOB region 105a/105b, including intervening metal gate lines 106 therebetween (in FIG. 4A) or free of intervening metal gate lines 106 therebetween (in FIG. 5A). In FIG. 4A, the metal gate lines 106 are separated from the lower channel patterns 104a by the isolation patterns 203 in the CSMOB region 105a/105b. In FIG. 5A, the conductive patterns 308 extend through the isolation patterns 203 on the surface of the lower channel structures 104, to directly contact at least one of the lower channel patterns 104a or gate patterns 206 in the CSMOB region 105a/105b. In the examples of FIGS. 4A and 5A, only one metal gate 106 and/or conductive pattern 308 is provided on the front side S1 of each lower channel structure 104, while two (or more) conductive patterns 308″ are provided on the back side S2 and extend through surface of the underlying substrate (in this example, the isolation region 226) opposite the lower channel structures 104 to contact at least one lower channel pattern 104a or gate pattern 206.

FIGS. 4B and 5B illustrate routing of the conductive patterns 308, 308′ on one side (illustrated as the front side S1 of the device 100) of the lower channel structures or stacks 104 in the CSMOB region 105a/105b, including intervening metal gate lines 106 therebetween (in FIG. 4B) or free of intervening metal gate lines 106 therebetween (in FIG. 5B). In FIG. 4B, the metal gate lines 106 are separated from the lower channel patterns 104a by the isolation patterns 203 in the CSMOB region 105a/105b. In FIG. 5B, the conductive patterns 308 extend through the isolation patterns 203 on the surface of the lower channel structures 104, to directly contact at least one of the lower channel patterns 104a or gate patterns 206 in the CSMOB region 105a/105b. In the examples of FIGS. 4B and 5B, two (or more) metal gates 106 and/or conductive patterns 308 are provided on the front side S1 of each lower channel structure 104.

FIGS. 4C and 5C illustrate routing of the conductive patterns 308, 308′, 308″ on both sides (illustrated as the front side S1 and the back side S2 of the device 100) of the lower channel structures or stacks 104 in the CSMOB region 105a/105b, including intervening metal gate lines 106 therebetween (in FIG. 4C) or free of intervening metal gate lines 106 therebetween (in FIG. 5C). In FIG. 4C, the metal gate lines 106 are separated from the lower channel patterns 104a by the isolation patterns 203 in the CSMOB region 105a/105b, while in FIG. 5C, the conductive patterns 308 extend through the isolation patterns 203 on the surface of the lower channel structures 104, to directly contact at least one of the lower channel patterns 104a or gate patterns 206 in the CSMOB region 105a/105b. In the examples of FIGS. 4C and 5C, two (or more) metal gates 106 and/or conductive patterns 308 are provided on the front side S1 of each lower channel structure 104, while only one conductive pattern 308″ is provided on the back side S2 and extending through surface of the underlying substrate (in this example, the isolation region 226) opposite the lower channel structure 104 to contact at least one lower channel pattern 104a or gate pattern 206.

FIGS. 4D and 5D illustrate routing of the conductive patterns 308, 308′, 308″ on both sides (illustrated as the front side S1 and the back side S2 of the device 100) of the lower channel structures or stacks 104 in the CSMOB region 105a/105b, including intervening metal gate lines 106 therebetween (in FIG. 4D) or free of intervening metal gate lines 106 therebetween (in FIG. 5D). In FIG. 4D, the metal gate lines 106 are separated from the lower channel patterns 104a by the isolation patterns 203 in the CSMOB region 105a/105b, while in FIG. 5D, the conductive patterns 308 extend through the isolation patterns 203 on the surface of the lower channel structures 104, to directly contact at least one of the lower channel patterns 104a or gate patterns 206 in the CSMOB region 105a/105b. In the examples of FIGS. 4D and 5D, two (or more) metal gates 106 and/or conductive patterns 308 are provided on the front side S1 of each lower channel structure 104, and two (or more) conductive patterns 308″ are provided on the back side S2 and extend through surface of the underlying substrate (in this example, the isolation region 226) opposite the lower channel structure 104 to contact at least one lower channel pattern 104a or gate pattern 206.

FIGS. 3A to 3D, 4A to 4D, and 5A to 5D are shown by way of example only to illustrate various possible configurations of metal gates 106 and conductive patterns 308 that are provided on the lower channel patterns 104a (free of the upper channel patterns 104b) in the CSMOB region 105a/105b in accordance with some embodiments of the present disclosure. It will be understood that embodiments of the present disclosure are not limited to these examples, but rather, may include additional configurations, for example, having fewer or more metal gates 106 and/or conductive patterns 308 on front side S1 and back side S2 surfaces of the device 100.

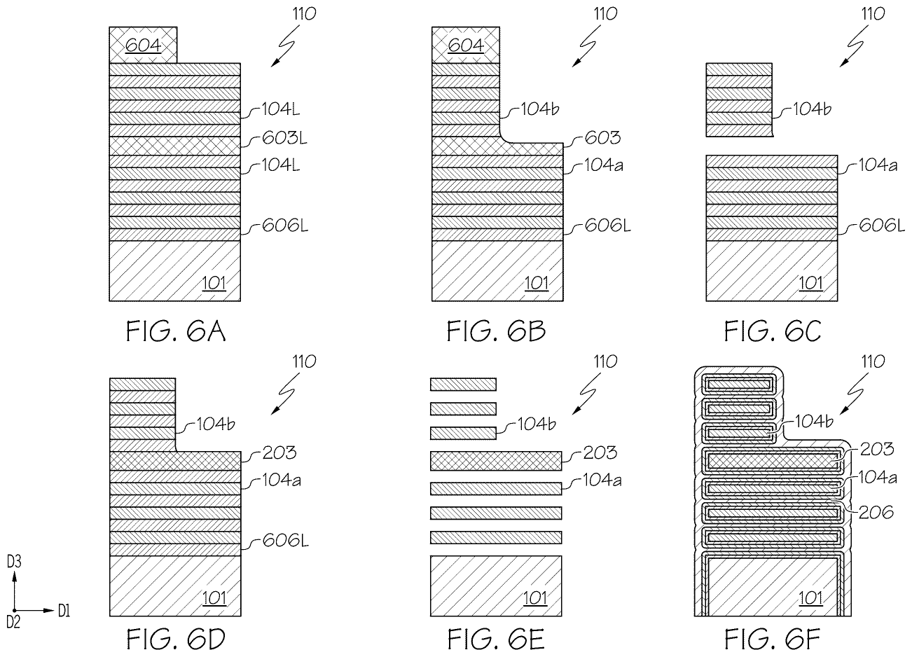

FIGS. 6A to 6F and FIGS. 7A to 7F are cross-sectional views taken along line C-C of FIG. 1B, illustrating example fabrication operations in methods of fabricating channel patterns in an active region 110 and in a CSMOB region 105a/105b, respectively, of a semiconductor integrated circuit device 100 according to some embodiments. FIG. 8 is a flowchart illustrating example fabrication operations in methods of fabricating channel patterns in the active region 110 and in the CSMOB region 105a/105b of a semiconductor integrated circuit device 100 according to some embodiments.

Referring to FIGS. 6A, 7A, and 8, the method includes forming channel layers 104L and sacrificial layers 606L alternately stacked on a substrate 101 in both the active region 110 and the CSMOB region 105a/105b (block 802). For example, the channel layers 104L may be silicon (Si) layers, which are to be utilized as channel regions 104a and 104b for lower and upper transistor devices 202a and 202b as described herein. The sacrificial layers 606L may be semiconductor material layers formed of a different semiconductor material (e.g., silicon germanium (SiGe) having etching selectivity with respect to the channel layers 104L. The sacrificial layers 606L may function as a placeholder for the gate patterns 206 of the lower and upper transistor devices 202a and 202b as described herein. An intermediary sacrificial layer 603L may be formed between a first subset of the alternating channel layers 104L and sacrificial layers 606L and a second subset of the alternating channel layers 104L and sacrificial layers 606L. The intermediary sacrificial layer 603L may be a semiconductor material layer having a different thickness and/or material composition (e.g., a different germanium concentration) than the sacrificial layers 606L, so as to provide etch selectivity. The intermediary sacrificial layer 603L may provide a placeholder for an isolation pattern (e.g., a middle dielectric layer 203) that separates lower and upper transistor devices 202a and 202b (or more particularly, the gate patterns 206 thereof) described herein.

Still referring to FIGS. 6A, 7A, and 8, a mask pattern 604 is formed on the channel layers 104L and sacrificial layers 606L in the active region 110 (block 804). The mask pattern 604 may expose portions of the channel layers 104L and sacrificial layers 606L in the active region 110. The mask pattern 604 may not be formed on the CSMOB region 105a/105b, such that the channel layers 104L and sacrificial layers 606L in the CSMOB region 105a/105b are exposed by the mask pattern 604.

Referring to FIGS. 6B, 7B, and 8, the method includes performing one or more etching process on the channel layers 104L, sacrificial layers 606L, and intermediary sacrificial layer 603L using the mask pattern 604 as an etching mask to form upper and lower channel structures 104 with a sacrificial isolation pattern 603 therebetween (block 806). The lower channel structures 104 include lower channel patterns 104a alternatingly stacked with sacrificial patterns 606, and the upper channel structures 104 include upper channel patterns 104b alternatingly stacked with sacrificial patterns 606. The channel patterns 104a and 104b may be nanosheet layers of the lower and upper transistor devices 202a and 202b as described herein in some embodiments.

As shown in FIG. 6B, as a result of the etching process(es), the upper channel patterns 104b in the active region 110 may be narrower than the lower channel patterns 104a (e.g., to form “L-shaped” stacked transistor structures TS), or may have substantially the same widths as the lower channel patterns 104a (e.g., to form “I-shaped” stacked transistor structures TS). However, as shown in FIG. 7B, as the mask pattern 604 is not formed on the CSMOB region 105a/105b, the channel layers 104L and sacrificial layers 606L corresponding to the upper channel structures 104 may be removed in the CSMOB region 105a/105b, such that the lower channel patterns 104a in the CSMOB region 105a/105b are free of upper channel patterns 104b thereon. That is, the etching process(es) may selectively remove the upper channel patterns 104b in the CSMOB region 105a/105b in the same fabrication operations used to form the lower and upper channel patterns 104a and 104b in the active region 110 in some embodiments.

Referring to FIGS. 6C and 7C, an additional selective etching process is performed to selectively remove the sacrificial isolation pattern 603 in both the active region 100 and the CSMOB region 105a/105b (e.g., based on the different thickness and/or material composition thereof relative to the sacrificial patterns 606). In particular, the sacrificial isolation pattern 603 may be formed of a material having an etch selectivity with respect to the lower channel patterns 104a, the upper channel patterns 104b, and the sacrificial patterns 606, such that the sacrificial isolation pattern 603 may be selectively removed. For example, the sacrificial isolation pattern 603 may include SiGe with a different Ge concentration from SiGe of the sacrificial patterns 606. However, the materials of the sacrificial patterns 606 and the sacrificial isolation pattern 603 are not limited to those described herein.

Referring to FIGS. 6D and 7D, an isolation pattern 203 is formed between the lower and upper channel patterns 104a and 104b in the active region 110, and on the lower channel patterns 104a in the CSMOB region 105a/105b, in the space from which the sacrificial isolation pattern 603 was selectively removed. The isolation pattern 203 may provide a middle dielectric isolation (MDI) on the stack of lower channel patterns 104a, thereby separating the lower channel patterns 104a of the lower transistor 202a from the upper channel patterns 104b of the upper transistor 202b in the active region 110.

Referring to FIGS. 6E and 7E, one or more further etching processes are performed to selectively remove the sacrificial patterns 606 between the stack of lower channel patterns 104a, and between the stack of upper channel patterns 104b. Referring to FIGS. 6F and 7F, one or more conductive layers are formed in the active region 110 to provide gate patterns 206 between the stack of lower channel patterns 104a, and between the stack of upper channel patterns 104b. The gate patterns 206 may include one or more conductive metal or semiconductor sublayers, which may be configured to provide work function adjustment for the lower and upper transistor devices 202a and 202b in some embodiments. The gate patterns 206 may or may not be formed between the stack of lower channel patterns 104a in the CSMOB region 105a/105b. That is, the gate replacement process may or may not be performed in the CSMOB region 105a/105b, such that the channel structures 104 in the CSMOB region 105a/105b may include the gate patterns 206 in some embodiments, or may include the sacrificial patterns 606L in other embodiments.

Referring again to FIG. 8, the method further includes forming conductive patterns (e.g., gates 106 and/or conductive patterns 308) on the lower channel patterns 104a in both the active region 110 and the CSMOB region 105a/105b (block 808). The conductive patterns may extend in a direction that intersects a direction of extension of the channel patterns 104a and 104b in the active region 110, but may extend in a same direction or aligned with the direction of extension of the lower channel patterns 104a in the CSMOB region 105a/105b. The conductive patterns may also be narrower than the lower channel patterns 104a in the CSMOB region 105a/105b, the conductive patterns 108. In some embodiments, the conductive patterns may be electrically isolated from the lower channel patterns 104a by the isolation patterns 203 (e.g., as shown in FIG. 3A), while in other embodiments, the conductive patterns may be formed to extend through the isolation patterns 203 and into the surfaces of the lower channel structures 104a (e.g., as shown in FIG. 3B). Also, in some embodiments, forming the conductive patterns may include patterning a backside surface S2 of a substrate to create openings therein, and forming the conductive patterns in the openings to contact at least one lower channel pattern 104a or gate pattern 206 of the lower channel structures 104 (e.g., as shown in FIGS. 3C and 3D).

According to some embodiments of the present disclosure, in a CSMOB region of an integrated circuit device (e.g., a 3DSFET) including at least two stacked transistors (e.g., lower and upper transistors), the lower channel pattern(s) (e.g., lower nanosheets) of a lower channel structure and the gates may be aligned in the same direction, while the upper channel pattern(s) (e.g., upper nanosheets) of the upper channel structure may be removed from the CSMOB region. In contrast, in a device region of the integrated circuit device, the gate may extend in a direction that is orthogonal to the direction of extension of the upper and lower channel patterns. In some embodiments, the upper channel patterns may or may not be present in the device region.

In some embodiments, a backside power distribution network structure of the integrated circuit device may be provided on a backside surface of a substrate that is opposite the channel patterns in the CSMOB region, and a lower metal line may be stacked onto a channel structure that is formed on an upper layer or frontside surface.

In the CSMOB region, the width of an upper gate or gate pattern (i.e., formed on the frontside of the device) may be narrower than the lower channel pattern(s) of the lower channel structure, and one or more conductive layers may be provided on (i.e., above) the lower channel structure. In some embodiments, a gate pattern may not be present in the CSMOB region, and conductive patterns (such as metal lines) may be provided on the lower channel structure free of the gate therebetween. For example, one or more metal lines may be formed in or on the channel patterns of the CSMOB region on the frontside of the device. Similarly, on the backside of the device, the width of the conductive patterns may be adjusted and may be narrower than the lower channel pattern(s) of the lower channel structure. For example, the number of metal lines may be one or more in the backside structure.

Embodiments of the present disclosure may thereby provide different epitaxial structures in the CSMOB region (e.g., including the lower channel patterns free of the upper channel patterns thereon) in comparison to the device active region (which may include the lower channel patterns, the upper channel patterns, and the MDI therebetween). By selectively removing the upper channel patterns from the lower channel patterns in the CSMOB region, the upper channel patterns (and any conductive patterns thereon) may be prevented from being released during fabrication operations to remove the MDI layer between the upper and lower channel structures. Also, different arrangements of conductive patterns (including gates and/or metal lines) may be provided in the CSMOB in comparison to the device active region. For example, the CSMOB may include gates or other conductive lines that extend in the same direction as the underlying lower channel patterns, are narrower than the lower channel patterns, and/or are provided on top (frontside) or on the bottom (backside) of the lower channel patterns. More generally, embodiments of the present disclosure may provide for improved or optimized epitaxial and/or conductive structures in the CSMOB region, so as to reduce or prevent unintentional release or delamination during subsequent fabrication processes performed on the device region, without requiring additional masking or other operations.

Advantages of structures, features, or operations disclosed herein may include, for example, the avoidance of cracks during dicing of a semiconductor chip and improved blocking of moisture penetration during packaging of the semiconductor chip, by removing the upper nanosheets (or other upper channel pattern(s)) from the CSMOB region, and optimizing the structure of metal lines and/or gates on the lower nanosheets (or other lower channel pattern(s) in the CSMOB region. Further, advantages of structures, features, or operations disclosed herein may include, for example, the avoidance of peeling (e.g., of the gate and/or the upper epitaxial structure) by removing the upper channel pattern(s) in areas outside the device region (e.g., in the CSMOB region), where the nanosheet or channel pattern size may be smaller (e.g., narrower) as compared to the device region. However, it will be understood that embodiments of the present disclosure are not limited to the above described advantages.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein. For example, as noted herein, an “insulating” layer or liner may include dielectric materials (which may be polarizable by an applied electric field).

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present disclosure. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Spatially relative terms such as “below” or “above” or “upper” or “lower” or “top” or “bottom” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the invention are also described with reference to a fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing detailed description.

1. A circuit device comprising:
a substrate comprising an active region and an inactive region adjacent a periphery of the active region;
lower channel structures respectively comprising one or more lower channel patterns stacked on the substrate in the active region and in the inactive region;
isolation patterns on the lower channel structures opposite the substrate; and
upper channel structures respectively comprising a one or more upper channel patterns stacked on the isolation patterns opposite the lower channel structures;
wherein the one or more lower channel patterns in the inactive region are free of the one or more upper channel patterns thereon.

2. The circuit device of claim 1, further comprising:
gates extending in a first direction on the one or more lower channel patterns in the active region and in the inactive region.

3. The circuit device of claim 2, wherein the one or more lower channel patterns in the inactive region extend in the first direction, and the one or more lower channel patterns in the active region extend in a second direction that intersects the first direction.

4. The circuit device of claim 1, further comprising:
one or more conductive patterns extending in a first direction on the one or more lower channel patterns in the inactive region, wherein the one or more conductive patterns are narrower than the lower channel patterns.

5. The circuit device of claim 4, wherein the one or more conductive patterns are on the one or more lower channel patterns in the inactive region free of metal gates therebetween.

6. The circuit device of claim 4, wherein the one or more conductive patterns extend through the isolation patterns in the inactive region opposite the substrate.

7. The circuit device of claim 4, wherein the one or more conductive patterns extend into a surface of the substrate that is opposite the lower channel structures in the inactive region to contact the lower channel structures.

8. The circuit device of claim 4, wherein the one or more conductive patterns respectively comprise a plurality of stacked metal patterns and/or conductive via structures on respective metallization levels of the circuit device.

9. The circuit device of claim 2, wherein the one or more upper channel patterns of the upper channel structures have respective widths that are narrower than those of the one or more lower channel patterns of the lower channel structures.

10. The circuit device of claim 1, wherein the inactive region is a crack stopper moisture barrier (CSMOB) region that extends along the periphery of the active region.

11. The circuit device of claim 1, wherein the one or more lower and upper channel patterns in the active region comprise lower and upper nanosheets extending between lower and upper source/drain regions of first and second transistors, respectively.

12. A circuit device comprising:
a substrate comprising an active region and a crack stopper moisture barrier (CSMOB) region extending along a periphery of the active region;
lower nanosheet stacks respectively comprising one or more lower nanosheet channel patterns stacked on the substrate in the active region and in the CSMOB region;
upper nanosheet stacks respectively comprising one or more upper nanosheet channel patterns stacked on the lower nanosheet stacks with respective isolation patterns therebetween; and
one or more conductive patterns extending in a first direction in the CSMOB region, wherein the conductive patterns are on the one or more lower nanosheet channel patterns in the CSMOB region free of the one or more upper nanosheet channel patterns therebetween.

13. The circuit device of claim 12, wherein the one or more lower nanosheet channel patterns in the CSMOB region are free of the one or more upper nanosheet channel patterns thereon.

14. The circuit device of claim 13, wherein the one or more conductive patterns in the CSMOB region comprise gates extending in the first direction on the one or more lower nanosheet channel patterns.

15. The circuit device of claim 14, wherein the one or more lower nanosheet channel patterns in the CSMOB region extend in the first direction, and the one or more lower nanosheet channel patterns in the active region extend in a second direction that intersects the first direction.

16. The circuit device of claim 12, wherein the one or more conductive patterns are narrower than the one or more lower nanosheet channel patterns.

17. The circuit device of claim 12, wherein the CSMOB region is free of metal gates, and the one or more conductive patterns in the CSMOB region extend through the respective isolation patterns and into the lower nanosheet stacks opposite the substrate.

18. The circuit device of claim 12, wherein, in the CSMOB region, the one or more conductive patterns extend into a surface of the substrate that is opposite the lower nanosheet stacks to contact the lower nanosheet stacks.

19. The circuit device of claim 12, wherein the one or more upper nanosheet channel patterns are narrower than the one or more lower nanosheet channel patterns.

20. A method of fabricating a circuit device, the method comprising:
forming channel layers and sacrificial layers that are alternately stacked on a substrate in an active region and in a crack stopper moisture barrier (CSMOB) region that extends along a periphery of the active region; and
performing at least one etching process on the channel layers and the sacrificial layers to form lower channel structures respectively comprising one or more lower channel patterns, sacrificial isolation patterns on the lower channel structures, and upper channel structures respectively comprising one or more upper channel patterns stacked on sacrificial isolation patterns opposite the lower channel structures, and to selectively remove the one or more upper channel patterns in the CSMOB region.

21.-26. (canceled)
